(19) United States
(12) Patent Application Publication
(10) Pub. No.: US 2026/0251710 A1
(43) Pub. Date: Aug. 27, 2026

(54) Method and system for testing three-dimensional semiconductor devices

(71) Applicant: Marvell Asia Pte Ltd, Singapore (SG)

(72) Inventors: Zahi S. Abuhamdeh, Billerica, MA (US); Shunquan Shen, Maynard, MA (US); Joseph Featherston, Brookline, MA (US); Nir Ofir, Yuvalim (IL); Carlos Macian Ruiz, Los Gatos, CA (US); Robb Oberst, Star, ID (US); Roger Mar, San Diego, CA (US); Seth Merriman, Eagle, ID (US); Nagaraj Shirali, Acton, MA (US)

(21) Appl. No.: 19/549,041

(22) Filed: Feb. 25, 2026

Related U.S. Application Data
(60) Provisional application No. 63/764,183, filed on Feb. 27, 2025.

(51) Int. Cl. G01R 31/3177

(52) U.S. Cl. CPC G01R 31/3177

(57) ABSTRACT

A method for testing a semiconductor assembly includes: in a three-dimensional (3D) multi-die assembly with a first die and a second die coupled by hybrid bond pad interconnects, operating a mission-mode datapath between the dies using bidirectional general purpose input output (GPIO) pads configured for a first signal direction in mission mode. In test mode, at least a subset of the GPIO pads operate in a second signal direction different from the first signal direction to form at least one on-die loopback path. Test data is injected into the mission-mode datapath at an injection point not on a critical timing path for mission-mode operation of the mission-mode datapath. Received test data is monitored through the on-die loopback path to detect at least one interconnect defect associated with the hybrid bond pad interconnects.

### CROSS-REFERENCE TO RELATED APPLICATIONS

This application claims the benefit of U.S. Provisional Patent Application 63/764,183, filed February 27, 2025, whose disclosure is incorporated herein by reference.

### FIELD OF THE DISCLOSURE

The present disclosure relates generally to testing of semiconductor devices, and more particularly but not exclusively to Built-In Self-Test (BIST) mechanisms for three-dimensional multi-die integrated circuit assemblies.

### BACKGROUND

Three-dimensional (3D) integrated circuit assemblies represent an advancement in semiconductor packaging technology that enables multiple dies to be vertically stacked and interconnected. Such assemblies can provide increased functionality and performance within a reduced footprint compared to traditional two-dimensional arrangements. In 3D multi-die configurations, a plurality of interconnections is established between stacked dies to facilitate communication and data transfer between the various circuit components distributed across the dies.

Hybrid bonding techniques have emerged as a method for creating high-density interconnections between stacked dies. Hybrid bond pads enable face-to-face bonding of dies, allowing for a large number of electrical connections to be established at the interface between the dies. The number of interconnections in such assemblies can range from tens of thousands to hundreds of thousands, depending on the application and die sizes involved.

The manufacturing and assembly processes for 3D multi-die semiconductor assemblies involve multiple steps, including wafer fabrication, die singulation, and die-to-die bonding. Each of these steps can introduce potential defects or variations that may affect the functionality of the interconnections between the stacked dies. Testing methodologies are employed at various stages of the manufacturing process to identify defects and ensure proper operation of the assembled devices. Testing methodologies for multi-die semiconductor assemblies may involve various considerations related to the interconnections between stacked dies.

The description above is presented as a general overview of related art in this field and should not be construed as an admission that any of the information it contains constitutes prior art against the present patent application.

### SUMMARY

An embodiment of the present invention that is described herein provides a method for testing a semiconductor assembly, the method including, in a three-dimensional (3D) multi-die semiconductor assembly that includes a first die and a second die coupled by a plurality of hybrid bond pad interconnects, operating a mission-mode datapath between the first die and the second die using bidirectional general purpose input output (GPIO) pads that are configured for a first signal direction during a mission mode. In a test mode, at least a subset of the bidirectional GPIO pads are operated at a second signal direction different from the first signal direction to form at least one on-die loopback path. Test data is injected into the mission-mode datapath at an injection point that is not on a critical timing path for a mission-mode operation of the mission-mode datapath. Received test data is monitored through the at least one on-die loopback path to detect at least one interconnect defect associated with the plurality of hybrid bond pad interconnects.

In some embodiments, circuitry used for test injection and test monitoring is not in series with the critical timing path for the mission-mode operation during the mission mode and the at least one on-die loopback path is formed on one of the first die and second die. In other embodiments, operating the at least a subset of the bidirectional GPIO pads includes reusing an output driver, which is idle during the mission mode, to drive a return signal into an input pad to implement the at least one on-die loopback path. In yet other embodiments, the monitoring is performed using receive circuitry of the mission-mode datapath, and the method further includes selectively enabling a test buffer, which is idle during the mission mode, while a mission buffer remains idle in the test mode.

In some embodiments, the method further includes injecting a test clock via a primary clock input pad to clock downstream test logic, and the injected test clock is provided on a non-timing-critical clock path relative to a timing-critical stacked clock loop between the first die and the second die. In other embodiments, the method further includes executing a built-in self-test (BIST) algorithm configured to detect single-bit failures in the plurality of hybrid bond pad interconnects using the at least one on-die loopback path, and executing the BIST algorithm includes applying at least one stress pattern selected from: an all-ones pattern, an all-zeros pattern, a checkerboard pattern, and an inverse-checkerboard pattern. In yet other embodiments, the method further includes executing a built-in self-test (BIST) algorithm configured to operate with partially populated interconnects by analyzing only a subset of payload bits that are physically connected, the BIST algorithm is executed using the at least one on-die loopback path.

In some embodiments, the method further includes generating a repair control for a redundancy scheme in response to defects detected by the monitoring, the redundancy scheme including per-wire repair within a group of wires. In other embodiments, the redundancy scheme further includes: performing, by a deskew block on a receive side of the mission-mode datapath, timing alignment of received signals by compensating for inter-wire delay differences, and performing, by a repair module on the receive side, reverse mapping corresponding to mapping performed by repair logic on a transmit side of the mission-mode datapath, thereby reconstructing an original data word. In yet other embodiments, generating the repair control includes storing repair configuration in at least one of a non-volatile fuse storage, and a programmable configuration storage, the repair configuration including at least one of: test results, enable bits, lane disable flags, and wire disable flags.

In some embodiments, in the monitoring, a detected failure in the at least one on-die loopback path is not required to distinguish whether a defect is on a transmit side or a receive side of the mission-mode datapath, and a repair of the detected failure is performed at the 3D multi-die semiconductor assembly by configuring repair mapping to map one or more lanes to a functioning transmitter and a functioning receiver, each of the one or more lanes includes one or more interconnect conductors of the plurality of hybrid bond pad interconnects used to convey a respective data signal between the first die and the second die. In other embodiments, injecting test data includes selecting a built-in self-test (BIST) test path that merges with the mission-mode datapath at the injection point prior to transmission over the bidirectional GPIO pads.

In some embodiments, the method further includes shmooing the 3D multi-die semiconductor assembly by varying at least one operating parameter during the test mode to validate operation of the mission-mode datapath. In other embodiments, the method further includes, in response to a single failure indication produced by the monitoring, selecting a repair that applies to a transmitter-side lane and a receiver-side lane associated with a same interconnect, without distinguishing whether a defect is on a transmit side or a receive side of the mission-mode datapath.

There is additionally provided, in accordance with an embodiment of the present invention, a system for testing a semiconductor assembly, the system includes (a) a first die including a transmit circuit and a receive circuit coupled to a plurality of bidirectional general purpose input output (GPIO) pads, (b) a second die configured to be coupled to the first die by a plurality of hybrid bond pad interconnects that are connected to the plurality of bidirectional GPIO pads, (c) control logic configured to, (i) in a mission mode, set the plurality of bidirectional GPIO pads to a first signal direction for a mission-mode data transfer, and, (ii) in a test mode, switch at least a subset of the plurality of bidirectional GPIO pads to a second signal direction different from the first signal direction to create at least one on-die loopback path, (d) a test-data injection circuit configured to inject test data into a mission-mode datapath at an injection point that is not on a critical timing path for a mission-mode operation of the mission-mode datapath, and (e) a test monitor configured to monitor received test data through the at least one on-die loopback path to detect at least one interconnect defect associated with the plurality of hybrid bond pad interconnects.

In some embodiments, the circuitry used for test injection and test monitoring is not in series with the critical timing path for the mission-mode operation during the mission mode and the control logic is configured to enable wafer sort testing on the first die by using the at least one on-die loopback path prior to coupling the second die to the first die. In other embodiments, the system further includes a test clock injection path coupled to a primary clock input pad, the test clock injection path configured to provide a test clock on a non-timing-critical path during wafer sort testing. In yet other embodiments, the system further includes repair logic configured to perform per-wire repair within a wire group.

The present disclosure will be more fully understood from the following detailed description of the embodiments thereof, taken together with the drawings in which:

### BRIEF DESCRIPTION OF THE DRAWINGS

FIG. 1 is a schematic, pictorial illustration of a semiconductor assembly comprising a top die and a bottom die in a three-dimensional stacked configuration, in accordance with an embodiment that is described herein;

FIG. 2 is a block diagram that schematically illustrates an interface between the top die and the bottom die with hybrid bond pad interconnects in the semiconductor assembly of FIG. 1, in accordance with an embodiment that is described herein;

FIG. 3 is a block diagram that schematically illustrates a test configuration for the semiconductor assembly of FIG. 1 with transmit modules, receive modules, and Built-In Self-Test (BIST) engines, in accordance with an embodiment that is described herein;

FIG. 4 is a block diagram that schematically illustrates a transmit module of the dies of FIG. 1, the transmit module is configured for mission mode signal flow and testing signal generation with loopback paths, in accordance with an embodiment that is described herein;

FIG. 5 is a block diagram that schematically illustrates a receive module of the dies of FIG. 1, the receive module is configured for mission mode and test mode operations with loopback paths, in accordance with an embodiment that is described herein;

FIG. 6 is a block diagram that schematically illustrates a built-in self-test loopback configuration implemented in a single die of the semiconductor assembly of FIG. 1 for wafer sort testing, in accordance with an embodiment that is described herein;

FIG. 7 is a block diagram that schematically illustrates a test clock injection configuration for wafer sort testing in the semiconductor assembly of FIG. 1, in accordance with an embodiment that is described herein;

FIG. 8 is a block diagram that schematically illustrates a lane redundancy architecture for the semiconductor assembly of FIG. 1, in accordance with an embodiment that is described herein; and

FIG. 9 is a flowchart that schematically illustrates a method for testing a semiconductor assembly, such as the three-dimensional multi-die semiconductor assembly of FIG. 1, in accordance with an embodiment that is described herein.

### DETAILED DESCRIPTION OF EMBODIMENTS

Three-dimensional multi-die semiconductor assemblies utilizing hybrid bond pad interconnects present significant testing challenges that are not adequately addressed by conventional built-in self-test (BIST) approaches. In such assemblies, tens of thousands to hundreds of thousands of interconnections are established between stacked dies through hybrid bonding processes, and these interconnections must be verified for proper functionality during manufacturing. Current solutions for testing these interconnections typically insert BIST engines directly into the functional signal path, which creates substantial performance penalties. Because the test circuitry is placed in series with the mission-mode data path, the timing-critical signals experience additional delay and timing uncertainty that can significantly degrade the high-speed performance of the interface. Furthermore, existing solutions are not designed as add-on extensions to mission-mode interfaces but rather require translation of the existing interface architecture into a protocol that can be processed by the test circuitry, adding complexity and integration burden. The performance and complexity of these conventional approaches have proven prohibitive for high-speed die-to-die interfaces where timing margins are stringent.

Embodiments that are described herein address these challenges by providing a built-in self-test (BIST) mechanism that utilizes the existing mission-mode hardware and leverages the bidirectional nature of GPIO pads to create on-die loopback paths for testing without inserting test circuitry into the timing-critical signal path. In some embodiments, the bidirectional pads that are configured for a single direction during mission mode are operated in an opposite direction during test mode to route transmitted signals back to receive circuitry, enabling verification of the transmit and receive hardware using the same datapath components employed during normal operation. In an example implementation, output drivers that would otherwise be idle during certain operating modes are repurposed to drive return signals into input pads, creating on-chip test paths that do not interfere with the mission-mode signal propagation timing. In certain embodiments, test data is injected into the mission-mode datapath at an injection point that is not on the critical timing path, and test monitoring circuitry similarly operates outside the timing-critical loop, preserving the performance characteristics that physical design optimization has achieved for the mission-mode interface.

In some embodiments, a test clock is injected via a primary clock input pad on a non-timing-critical path, avoiding the latency penalties that would result from using the timing-critical stacked clock loop between the top die and bottom die. In some embodiments, the BIST algorithm is configured to detect single-bit failures and can operate with partially populated interconnects by analyzing only the subset of payload bits that are physically connected. In an example implementation, the system applies stress patterns such as all-ones, all-zeros, checkerboard, and inverse-checkerboard patterns to verify proper operation under various signal conditions.

In some embodiments, a redundancy scheme provides resilience against manufacturing defects through per-wire repair within groups of wires, enabling recovery from single-wire failures. In an example implementation, when a failure is detected during wafer sort testing, the system does not distinguish whether the defect is on the transmit side or receive side, and repair mapping is configured to map lanes to functioning transmitters and receivers, which advantageously improves yield recovery when assembling dies of different sizes where the larger die is statistically more likely to have defects.

The disclosed techniques preserve the timing-critical mission-mode signal paths while enabling comprehensive testing of the hybrid bond pad interconnects. By reusing the mission-mode hardware and operating the bidirectional pads in a loopback configuration, the test mechanism avoids the performance penalties associated with inserting test circuitry into the functional path. The approach enables wafer sort testing of individual dies prior to assembly, allowing defective dies to be identified and discarded before the costly bonding process. The redundancy scheme provides yield recovery at the assembled module level, and the ability to repair failures without distinguishing between transmit-side and receive-side defects simplifies the repair process while maximizing the probability of successful recovery when dies with different defect profiles are assembled together.

The description above is presented as a general overview of embodiments of the present disclosure, which are described in detail herein.

### DEFINITIONS

In the present context, the term "semiconductor assembly" may refer to an integrated circuit structure comprising multiple dies that are physically and electrically connected to form a functional unit. An example of a semiconductor assembly is a three-dimensional stacked configuration where a top die containing processor cores is bonded to a bottom die containing routing and cache resources. Another example of a semiconductor assembly is a three-dimensional stacked configuration where a top die containing of or more memory devices, which is bonded to a bottom die containing processor cores.

In the present context, the term "three-dimensional (3D) multi-die semiconductor assembly" may refer to a semiconductor package configuration in which two or more dies are vertically stacked and interconnected through bonding techniques that establish electrical connections between the dies. An example of a 3D multi-die semiconductor assembly is a configuration where chiplets are bonded to a larger base die using hybrid bond pads to create at least tens of thousands of interconnections.

In the present context, the term "hybrid bond pad interconnect" may refer to an electrical connection structure formed at the interface between two dies in a face-to-face bonding configuration, enabling high-density signal transfer between the stacked dies. An example of a hybrid bond pad interconnect is a copper-to-copper bond formed during a heating process that establishes both mechanical and electrical connection between a top die and a bottom die.

In the present context, the term "mission-mode datapath" may refer to the signal routing path used during normal functional operation of the semiconductor assembly for transferring data between dies or between circuit components. An example of a mission-mode datapath is the high-speed data transmission path between a transmit module on a bottom die and a receive module on a top die during normal system operation.

In the present context, the term "bidirectional general purpose input output (GPIO) pad" may refer to an input/output structure that can be configured to operate as either an input or an output depending on the operating mode of the circuit. An example of a bidirectional GPIO pad is an IO-Light pad that is configured as an output during mission mode data transmission but can be switched to operate as an input during test mode to create a loopback path.

In the present context, the term "mission mode" may refer to the normal functional operating state of the semiconductor assembly in which data is transferred between dies for system operation rather than for testing purposes. An example of mission mode is the state in which circuitry on a top die communicates with resources on a bottom die through the hybrid bond pad interconnects.

In the present context, the term "test mode" may refer to an operating state of the semiconductor assembly in which test data is injected and monitored to verify proper functionality of the interconnections and circuitry. An example of test mode is the state during wafer sort testing in which built-in self-test patterns are transmitted through loopback paths to detect defective interconnects.

In the present context, the term "on-die loopback path" may refer to a signal routing configuration within a single die that routes transmitted signals back to receive circuitry without requiring an external connection or a second die. An example of an on-die loopback path is a configuration where the output of a transmit module is routed through a bidirectional pad back to the input of a receive module on the same die.

In the present context, the term "critical timing path" may refer to the signal path within a circuit that determines the maximum operating speed due to having the longest propagation delay or most stringent timing constraints. An example of a critical timing path is the mission-mode data path through a Double Data Rate (DDR) encoder and clock alignment circuitry that physical design optimization targets for achieving high-speed operation.

In the present context, the term "injection point" may refer to a location in a circuit where test data can be introduced into the datapath for testing purposes. An example of an injection point is the location where a Built-In Self-Test (BIST) test path merges with the mission-mode datapath prior to transmission over the bidirectional GPIO pads.

In the present context, the term "interconnect defect" may refer to a manufacturing fault or failure in the electrical connections between dies that prevents proper signal transmission. An example of an interconnect defect is a broken wire or failed hybrid bond pad that causes data corruption when signals are transmitted between the top die and bottom die.

In the present context, the term "output driver" may refer to a circuit element that provides the electrical drive strength to transmit signals from a die to an external connection or to another die. An example of an output driver is the buffer circuit within a bidirectional GPIO pad that drives signals onto the hybrid bond pad interconnect during transmission.

In the present context, the term "test buffer" may refer to a buffer circuit that is activated during test mode to support test operations while remaining idle during mission mode. An example of a test buffer is the yellow-designated buffer in a receive module that is enabled during BIST operations to capture loopback test data.

In the present context, the term "mission buffer" may refer to a buffer circuit that is used during normal functional operation of the semiconductor assembly and may be disabled during test mode. An example of a mission buffer is the red-designated buffer in a receive module that processes received data during mission-mode communication between dies.

In the present context, the term "test clock" may refer to a clock signal that is injected during test mode to provide timing for test operations. An example of a test clock is a clock signal injected via a primary clock input pad during wafer sort testing when the bottom die is not present to provide the normal clock signal.

In the present context, the term "primary clock input pad" may refer to an input connection point on a die or a chiplet that receives a clock signal for timing circuit operations. An example of a primary clock input pad is the pad through which a test clock is injected during wafer sort testing to clock the test circuitry without using the timing-critical stacked clock loop.

In the present context, the term "timing-critical stacked clock loop" may refer to the clock signal path between stacked dies that has stringent timing requirements and determines the maximum operating frequency of the interface. An example of a timing-critical stacked clock loop is the clock path from a bottom die to a top die and back to the bottom die that must be minimized to achieve high-speed operation.

In the present context, the term "built-in self-test (BIST) algorithm" may refer to a test procedure implemented within the semiconductor assembly that generates test patterns and analyzes responses to detect defects without requiring external test equipment for pattern generation and response analysis. An example of a BIST algorithm is a test sequence that applies all-ones, all-zeros, and checkerboard patterns to detect single-bit failures in the hybrid bond pad interconnects.

In the present context, the term "stress pattern" may refer to a test data pattern designed to exercise the circuit under conditions that may reveal defects or weaknesses. An example of a stress pattern is a power hammer pattern that applies all-ones and all-zeros values to stress the power rails of the interface.

In the present context, the term "partially populated interconnects" may refer to an interface configuration in which only a subset of the available interconnect positions are physically connected and used for data transfer. An example of partially populated interconnects is a 16-bit interface where only 6 bits are balled out and connected, with the remaining positions unused.

In the present context, the term "repair control" may refer to configuration information or signals that direct the redundancy scheme to reroute signals around defective interconnects. An example of repair control is the fuse or register settings that configure lane repair multiplexers to bypass a failed wire.

In the present context, the term "redundancy scheme" may refer to a design approach that includes spare resources to enable continued operation when defects are present. An example of a redundancy scheme is a configuration that includes spare wires within each group for per-wire repair.

In the present context, the term "per-wire repair" may refer to a repair mechanism that replaces individual defective wires within a group using spare wires allocated to that group. An example of per-wire repair is the use of lane repair multiplexers to route data around a single failed wire within a 16-bit bundle.

In the present context, the term "wire group" may refer to a collection of interconnect wires that are managed together for purposes of data transfer and repair. An example of a wire group is a 16-bit grouping of wires that includes spare capacity for per-wire repair.

In the present context, the term "repair mapping" may refer to the configuration that specifies how data lanes are assigned to physical interconnects to avoid defective connections. An example of repair mapping is the fuse settings that direct data intended for a failed wire to be routed through a spare wire.

In the present context, the term "lane" may refer to one or more interconnect conductors used to convey a respective data signal between dies. An example of a lane is a single wire within a bundle that carries one bit of data between the transmit module and receive module.

In the present context, the term "transmit circuit" may refer to circuitry that prepares and sends data signals from a die to another die or external connection. An example of a transmit circuit is a Tx module that includes clock alignment, DDR encoding, and output driver circuitry.

In the present context, the term "receive circuit" may refer to circuitry that receives and processes data signals arriving at a die from another die or external connection. An example of a receive circuit is an Rx module that includes input buffers, DDR decoding, and receive First-In, First-Out (FIFO) circuitry.

In the present context, the term "control logic" may refer to circuitry that manages the configuration and operation of other circuit components based on the operating mode. An example of control logic is the circuitry that switches bidirectional GPIO pads between mission mode and test mode configurations.

In the present context, the term "test-data injection circuit" and "injection circuitry" may refer to circuitry that introduces test patterns, typically at an "injection point," into the datapath during test mode. Therefore, the terms "test-data injection circuit," "injection circuitry," and "injection point" may be used interchangeably. An example of a test-data injection circuit is a multiplexer structure that selects between mission-mode data and BIST-generated test data.

In the present context, the term "test monitor" may refer to circuitry that observes received test data and compares it against expected values to detect defects. An example of a test monitor is a BIST checker that analyzes loopback data to identify single-bit failures.

In the present context, the term "wafer sort testing" may refer to testing performed on dies while they are still part of a semiconductor wafer, prior to singulation and assembly. An example of wafer sort testing is BIST execution on individual dies using on-die loopback paths before the dies are bonded together.

In the present context, the term "test clock injection path" may refer to the signal routing used to provide a test clock to circuit components during test mode. An example of a test clock injection path is the non-timing-critical path from a primary clock input pad to downstream test logic.

In the present context, the term "repair logic" may refer to circuitry that implements the redundancy scheme by routing signals around defective interconnects. An example of repair logic is the lane repair multiplexers and bundle replacement switching circuitry.

In the present context, the term "BIST test path" may refer to the signal routing used to carry test data from a BIST engine to the injection point in the mission-mode datapath. An example of a BIST test path is the path from a BIST engine through selection circuitry to merge with the mission-mode datapath prior to transmission.

In the present context, the term "shmooing" may refer to a test technique that varies operating parameters to characterize the operating margins of a circuit. An example of shmooing is varying voltage and timing parameters during test mode to validate that the mission-mode datapath operates correctly across a range of conditions.

### SYSTEM DESCRIPTION

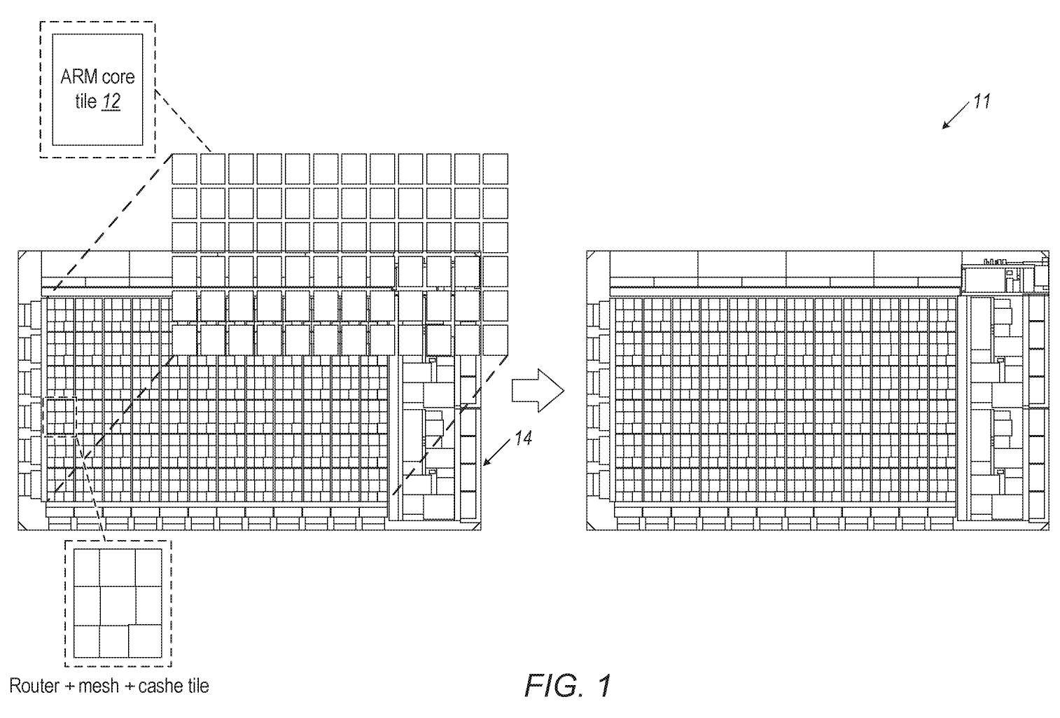

FIG. 1 is a schematic, pictorial illustration of a semiconductor assembly 11 comprising a top die 12 and a bottom die 14 in a three-dimensional stacked configuration, in accordance with an embodiment that is described herein. Semiconductor assembly 11 comprises circuitry on top die 12. Bottom die 14 serves as a larger base die that supports top die 12 and comprises routing and interface circuitry, as well as Through-Silicon Via (TSV) structures for interconnection. The left portion of FIG. 1 shows an exploded view of semiconductor assembly 11, depicting top die 12 positioned above bottom die 14 prior to assembly. Top die 12 contains functional circuitry.

In some embodiments, the right portion shows the assembled semiconductor assembly 11 with top die 12 (e.g., a plurality of chiplets) is bonded to bottom die 14. In this assembled configuration, the circuitry of top die 12 is aligned with corresponding interface regions on bottom die 14. Bottom die 14 provides interconnect routing resources that support communication with the circuitry on top die 12, e.g., a chiplet whose properties are described below. Semiconductor assembly 11 utilizes hybrid bond pad interconnects to establish communication paths between top die 12 and bottom die 14, enabling high-density signal transfer between the stacked dies. In the present example, the plurality of hybrid bond pad interconnects number in the tens of thousands to hundreds of thousands between the bonded chips, providing the bandwidth required for communication between top die 12 and bottom die 14. Notably, the number of hybrid bond pad interconnects may be scaled to millions and billions in future generations.

In some embodiments, bottom die 14 is a large die while each of top die 12 comprises one or more smaller chiplets in semiconductor assembly 11. Top die 12 and bottom die 14 are bonded together through a heating process for hybrid bond pad assembly, which establishes both mechanical attachment and electrical connection between the stacked dies. The hybrid bonding process creates copper-to-copper bonds at the interface between top die 12 and bottom die 14, forming the high-density interconnections that enable the three-dimensional multi-die configuration of semiconductor assembly 11.

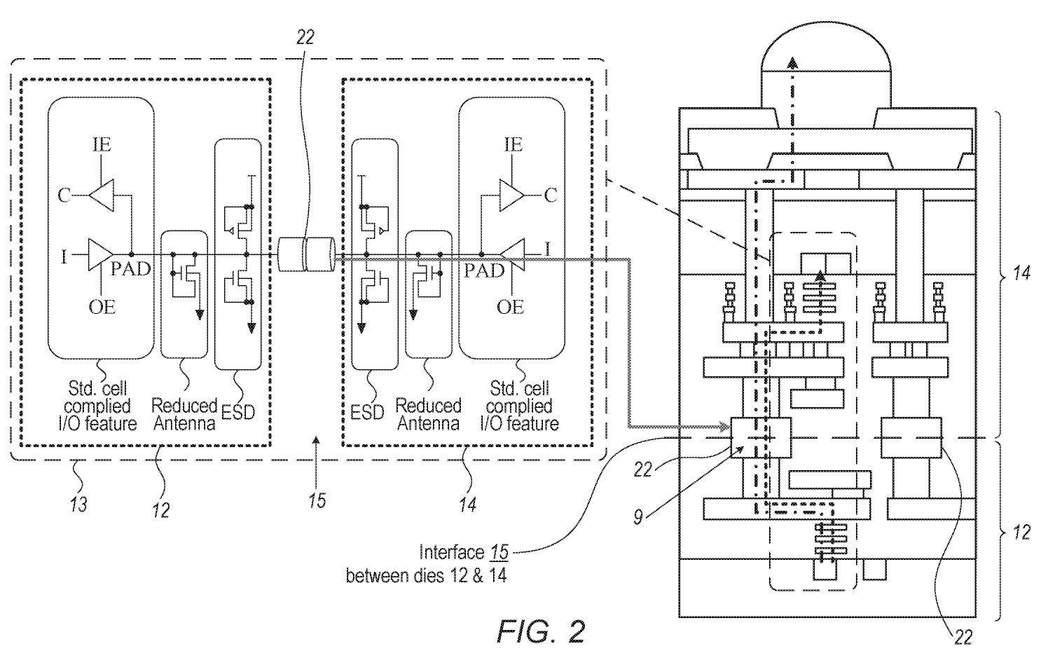

FIG. 2 is a block diagram illustrating an interface 15 between top die 12 and bottom die 14 in a three-dimensional multi-die configuration, in accordance with an embodiment that is described herein. In some embodiments, semiconductor assembly 11 comprises top die 12 positioned relative to bottom die 14 in the illustrated cross-sectional view, with interface 15 providing the connection layer between the two dies. Bottom die 14 comprises device circuitry and is coupled to top die 12 through interface 15. Top die 12 similarly comprises device circuitry and a cell structure, such as the chiplet described in FIG. 1 above. The assembly utilizes a plurality of hybrid bond pads 22 to establish electrical connections between top die 12 and bottom die 14.

In some embodiments, a first hybrid bond pad 22 is shown at the upper portion of the assembly providing a face-to-face connection, while a second hybrid bond pad 22 is indicated at the interface region. The plurality of hybrid bond pads 22 form the hybrid bond pad interconnects that couple top die 12 and bottom die 14 in the three-dimensional multi-die semiconductor assembly. Interface 15 between top die 12 and bottom die 14 uses General Purpose Input Output (GPIO) Light pads designed for three-dimensional interconnect applications. The GPIO Light pads provide bidirectional GPIO pad structures that can be configured for signal transfer in either direction depending on the operating mode.

Reference is now made to an inset 13 that provides a detailed view of the input/output circuitry associated with hybrid bond pads 22. In the present example, inset 13 shows bidirectional pad structures with Electrostatic Discharge (ESD) protection elements, reduced antenna structures, and associated control circuitry for both input and output operations. In some embodiments, the bidirectional GPIO pads shown in inset 13 are configured for a first signal direction during a mission mode, enabling operation of a mission-mode datapath between top die 12 and bottom die 14. The mission-mode datapath comprises a wide bus architecture with multiple parallel data lanes that transfer data between the stacked dies through the plurality of hybrid bond pad interconnects.

Reference is now made back to the general view of FIG. 2. In some embodiments, semiconductor assembly 11 comprises signal paths for IO signal connections and die-to-die signal connections, as well as power connections. Top metal layers connect to hybrid bond pads 22, and Through-Silicon Vias (TSVs) provide vertical interconnections within bottom die 14. The configuration enables high-density communication between top die 12 and bottom die 14 through the plurality of hybrid bond pad 22 interconnects at interface 15. Top die 12 comprises a transmit circuit and a receive circuit (described in detail below) coupled to the plurality of bidirectional GPIO pads, and bottom die 14 is configured to be coupled to top die 12 by the plurality of hybrid bond pad interconnects connected to the plurality of bidirectional GPIO pads.

In some cases, an interconnect defect 9 can occur at the hybrid bond pad connections during the manufacturing and assembly process. Interconnect defect 9 represents a manufacturing fault or failure in the electrical connections between dies that prevents proper signal transmission through the affected hybrid bond pad 22. The hybrid bonding process that creates copper-to-copper bonds at interface 15 can result in interconnect defect 9 due to any sort of fault, such as misalignment, contamination, or incomplete bonding. Because semiconductor assembly 11 comprises tens of thousands to hundreds of thousands of hybrid bond pad interconnects, the probability of at least one interconnect defect 9 occurring increases with the number of connections.

In some embodiments, detection of interconnect defect 9 through built-in self-test mechanisms enables identification of faulty interconnects and application of repair schemes to recover yield at the assembled module level.

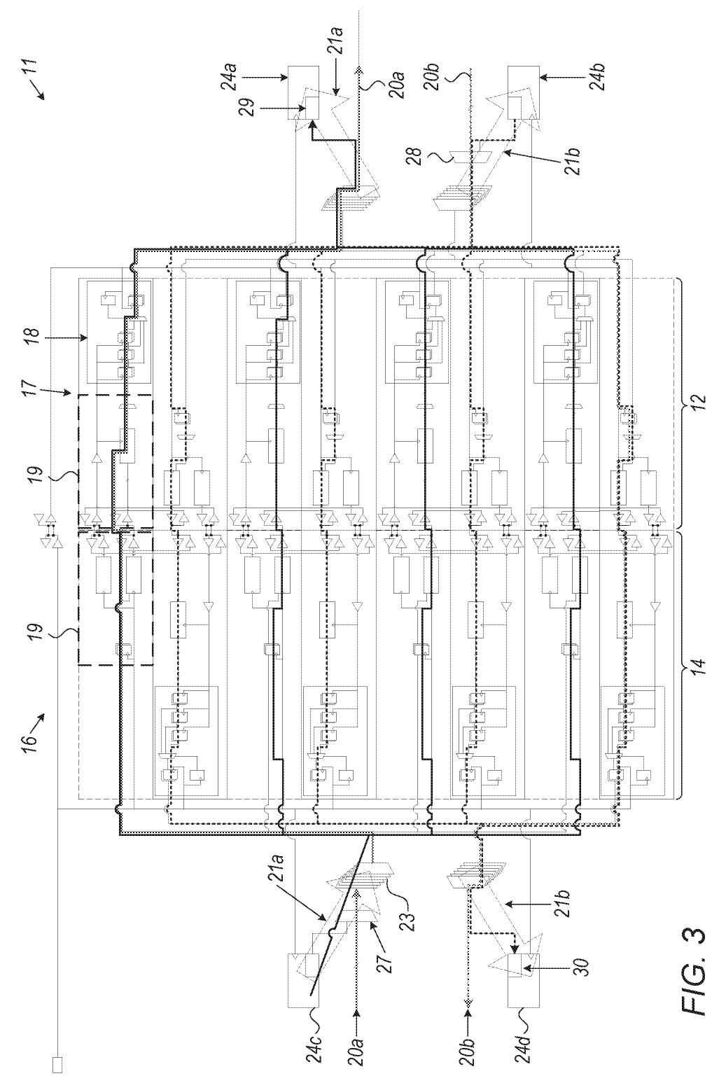

FIG. 3 is a block diagram that schematically illustrates a test configuration for semiconductor assembly 11 configured for testing interconnections between bottom die 14 and top die 12 in a three- dimensional multi-die configuration, in accordance with an embodiment that is described herein.

In some embodiments, semiconductor assembly 11 comprises a plurality of transmit (Tx) modules 16 and a plurality of (receive) Rx modules 17 arranged to facilitate data transfer between bottom die 14 and top die 12 through the hybrid bond pad 22 interconnects. Each Tx module 16 comprises high-speed hardware 19 that enables signal transmission from one die to another. Lane repair MUXs 23 are separate components in the assembly that provide the capability to reroute signals around defective interconnect lanes, and lane repair MUXs 23 are configured to repair at least one lane within a group of data lanes. Each Rx module 17 comprises a receive FIFO 18 for buffering incoming data and maintaining proper data alignment between the transmitting and receiving circuits.

In some embodiments, semiconductor assembly 11 operates in two distinct modes. In a mission mode, data flows through a mission mode Tx data path 20a and a mission mode Rx data path 20b, which represent the normal data paths in an assembled module. Mission mode Tx data path 20a carries data through the standard communication channels between bottom die 14 and top die 12 using high-speed hardware 19 of Tx module 16 and the receive circuitry of Rx module 17. Mission mode Rx data path 20b carries data in the reverse direction from top die 12 to bottom die 14. In some embodiments, mission mode Tx data path 20a and mission mode Rx data path 20b represent the functional operation of assembled semiconductor assembly 11 during normal use, where the plurality of bidirectional GPIO pads are set to a first signal direction for mission-mode data transfer.

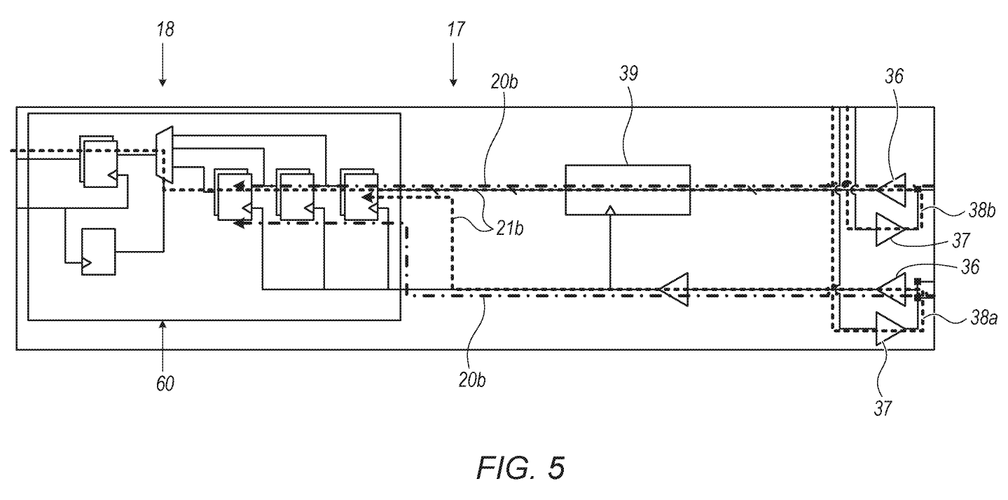

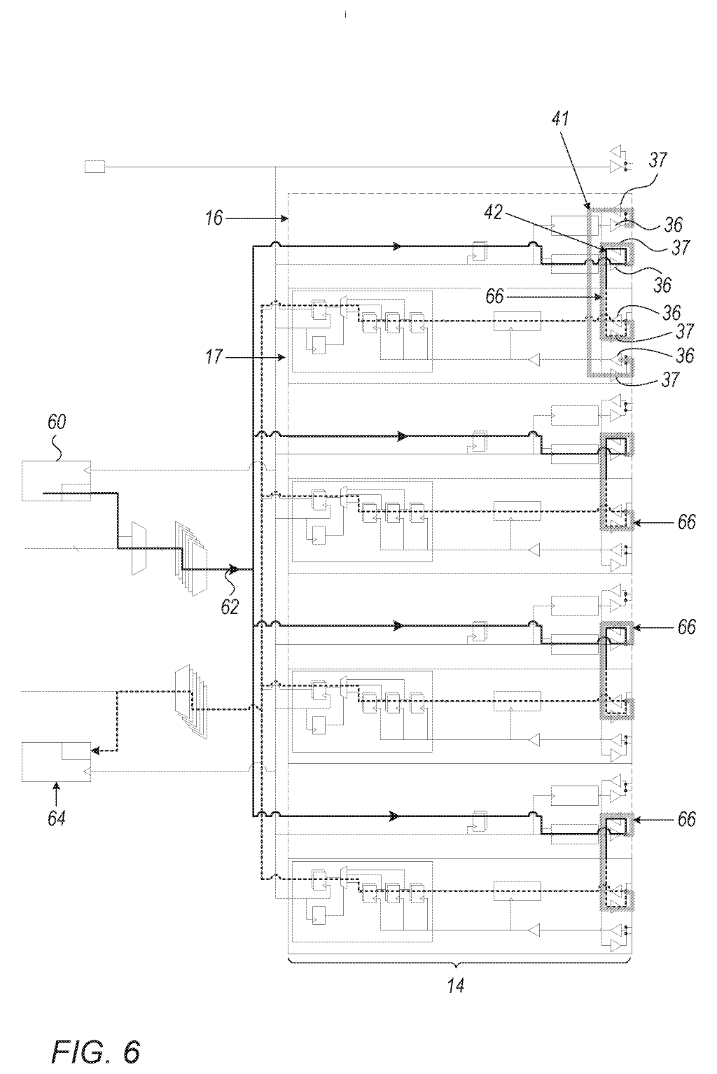

In some embodiments, in a test mode, semiconductor assembly 11 utilizes a test mode Tx data path 21a and a test mode Rx data path 21b. As described previously with respect to FIG. 2, the bidirectional GPIO pads can be operated for signal transfer in either direction depending on the operating mode. In the test mode, a control logic (shown a control logic 60 in FIGS. 5 and 6 below) is configured to switch at least a subset of the plurality of bidirectional GPIO pads to a second signal direction different from (e.g., opposit to) the first signal direction to create at least one on-die loopback path. The on-die loopback path is formed on at least one of top die 12 and bottom die 14, enabling wafer sort testing on the respective die prior to coupling the other die. In some embodiments, test mode Tx data path 21a and test mode Rx data path 21b enable injection of test data into the mission-mode datapath and monitoring of received test data to detect interconnect defect 9 without interfering with the critical timing paths used during mission mode Tx data path 20a and mission mode Rx data path 20b.

In some embodiments, semiconductor assembly 11 comprises a plurality of Built-In Self-Test (BIST) engines positioned on both bottom die 14 and top die 12. A BIST engine 24a and a BIST engine 24b are coupled to Tx module 16 and Rx module 17 shown on the right side of semiconductor assembly 11 are associated with top die 12. A BIST engine 24c and a BIST engine 24d are coupled to corresponding Tx and Rx modules on the left side associated with bottom die 14. In some embodiments, BIST engine 24a, BIST engine 24b, BIST engine 24c, and BIST engine 24d are configured to generate test patterns and analyze responses to detect defects in the hybrid bond pad interconnects.

In some embodiments, semiconductor assembly 11 comprises a test injection circuitry and injection point 27 and a test injection circuitry and injection point 28 that function as test-data injection circuits configured to inject test data into the mission-mode datapath at an injection point that is not on a critical timing path for mission-mode operation of the mission-mode datapath. Test injection circuitry 27 is associated with the transmit path on bottom die 14, while test injection circuitry 28 is associated with the receive path on top die 12. In some embodiments, the circuitry used for test injection is not in series with the critical timing path for mission-mode operation during the mission mode, preserving the timing characteristics that physical design optimization has achieved for the mission-mode interface.

In some embodiments, semiconductor assembly 11 further comprises Test monitoring 29 and Test monitoring 30 that function as test monitors configured to monitor received test data through the at least one on-die loopback path to detect at least one interconnect defect 9 associated with the plurality of hybrid bond pad interconnects. Test monitoring 29 is associated with the receive path on bottom die 14, while Test monitoring 30 is associated with the receive path on top die 12. The circuitry used for test monitoring is not in series with the critical timing path for mission-mode operation during the mission mode. In some embodiments, the configuration of test injection circuitry and points 27, 28 and Test monitoring 29, and 30 enables comprehensive testing of the hybrid bond pad interconnects while preserving the performance characteristics of mission mode Tx data path 20a and mission mode Rx data path 20b.

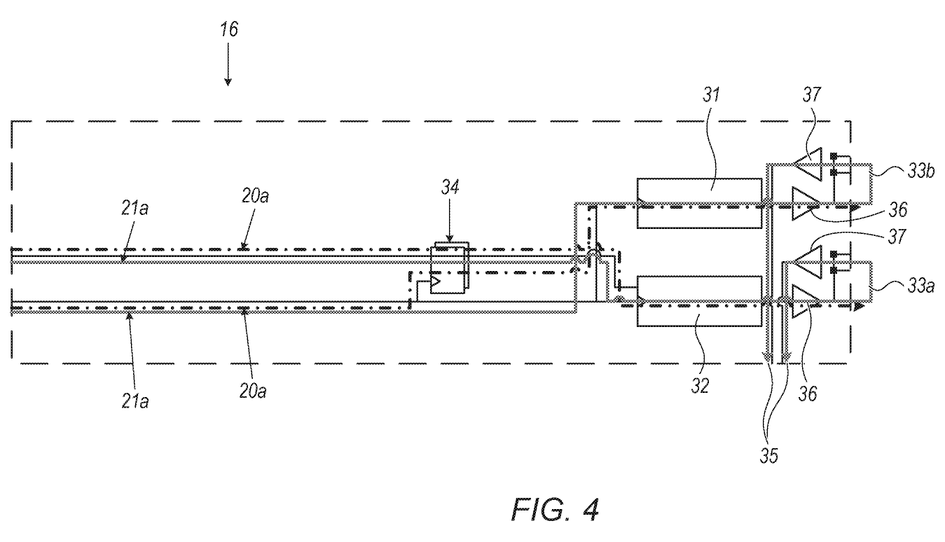

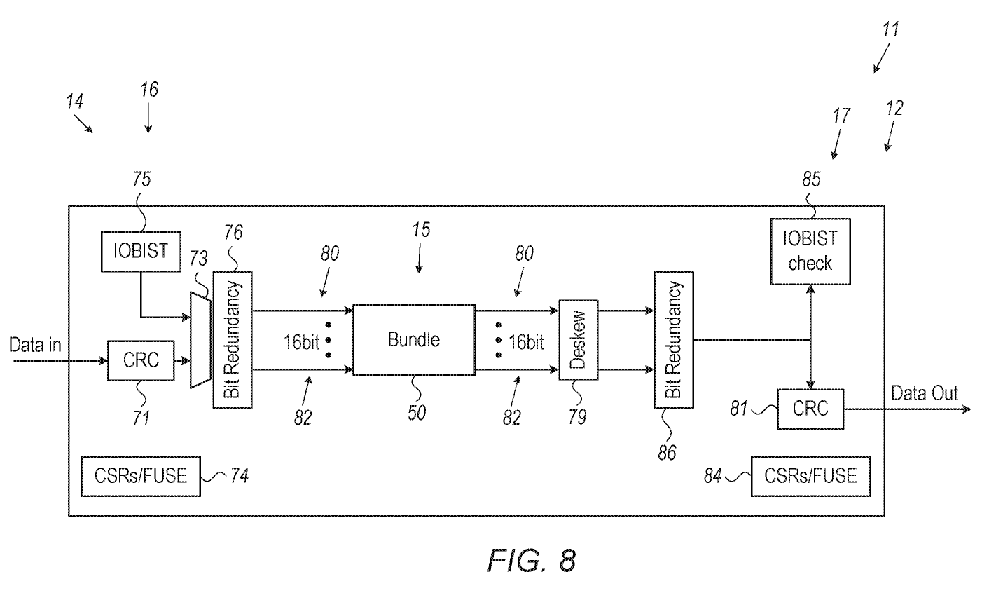

In some embodiments, the configuration shown in FIG. 3 comprises multiple replicated slices of Tx module 16 and Rx module 17 pairs, allowing for parallel data transmission across a wide bus interface. Lane repair MUXs 23 within each slice provide per-wire repair capability (shown in FIG. 8 below), enabling semiconductor assembly 11 to recover from single-wire failures within each group of interconnects. The control logic is configured to enable wafer sort testing on top die 12 or bottom die 14 by using the at least one on-die loopback path (shown for example in FIGS. 4-7 below) prior to coupling the other die, allowing defective dies to be identified before the bonding process.

FIG. 4 is a block diagram that schematically illustrates a transmit module (e.g., Tx module 16) configured for test signal generation with loopback paths, in accordance with an embodiment that is described herein. In some embodiments, Tx module 16 comprises a data path that carries mission-mode signals through the module. The data path 20a receives input data and routes it through pipelining flip-flops (FFs) 34 that provide timing alignment for the transmitted signals. In some embodiments, a BIST path 21a enters Tx module 16, providing an alternative signal source for built-in self-test operations. The data path and BIST path converge at selection circuitry that determines whether mission-mode data or test data is transmitted. Tx module 16 comprises a clock alignment 31 block that synchronizes the data signals with a transmit clock.

In some embodiments, a Double Data Rate (DDR) encoder 32 is configured to process the aligned signals to implement double data rate encoding, which transmits data on both rising and falling clock edges. The output of DDR encoder 32 drives the signals toward the hybrid bond pad interconnects. In some embodiments, Tx module 16 incorporates loopback paths for wafer sort testing. In some embodiments, a data loopback 33a and a clock loopback 33b allow the transmitted clock and data signals to be routed back into the receive circuitry without requiring the presence of a second die. Additionally, a loopback path 35 returns the transmitted data for verification by the BIST monitoring circuitry.

In some embodiments, the loopback paths utilize the bidirectional nature of the GPIO pads, repurposing output drivers that would otherwise be idle during certain operating modes to create on-die test paths that do not interfere with the timing-critical mission-mode signal paths. Additionally, a mission buffer 36 handles signals during normal operation, while a test buffer 37 is activated during BIST operations to capture loopback test data.

FIG. 5 is a block diagram that schematically illustrates Rx module 17 configured for mission mode and test mode operations in semiconductor assembly 11, in accordance with an embodiment that is described herein. In some embodiments, Rx module 17 comprises receive FIFO 18 positioned at the input side that buffers incoming data. A DDR decoder 39 processes the received signals and provides decoded data to downstream circuitry. DDR decoder 39 is configured to perform the inverse operation of DDR encoder 32 described with respect to FIG. 4 above, recovering the original data from the double data rate encoded signals received through the hybrid bond pad interconnects.

In some embodiments, Rx module 17 comprises distinct regions for mission buffer circuitry and test buffer circuitry. A first region contains test buffer 37 that is used during test mode operation. A second region contains mission buffer 36 that is used during mission mode operation. In some embodiments, the receive circuit of Rx module 17 comprises mission buffer 36 and test buffer 37, providing separate signal paths for the two operating modes.

In some embodiments, control logic 60 provides configuration and control signals to Rx module 17. Control logic 60 is configured to use mission buffer 36 in the mission mode and use test buffer 37 in the test mode. During mission mode operation, control logic 60 enables mission buffer 36 to process received data through mission mode Rx data path 20b while test buffer 37 remains idle. During test mode operation, control logic 60 selectively enables test buffer 37, which is idle during the mission mode, while mission buffer 36 remains idle. In some embodiments, test buffer 37 is repurposed (e.g., by control logic 60) from an idle state during mission mode to active use during test mode, enabling the monitoring of received test data without requiring additional circuitry in the timing-critical mission-mode datapath.

In some embodiments, Rx module 17 comprises loopback paths for wafer sort testing. A data loopback 38a and a clock loopback 38b are indicated, showing loopback enabled paths that utilize the bidirectional nature of the GPIO pads to route transmitted signals back to the receiver circuitry without requiring the presence of a second die. Data loopback 38a routes test data signals from the output pads back to the input circuitry of Rx module 17, and clock loopback 38b routes the clock signal. In some embodiments, clock alignment 31 (shown in FIG. 4 above) is configured to synchronize the received signals with the local clock domain, enabling proper data capture through the loopback paths.

In some embodiments, the monitoring of received test data is performed using receive circuitry of the mission-mode datapath. Rx module 17 utilizes the same DDR decoder 39 and the signal that passed through clock alignment 31 circuitry (shown in FIG. 4 above) for both mission mode and test mode operations, with the distinction being whether mission buffer 36 or test buffer 37 captures the decoded data. The disclosed configuration enables comprehensive testing of the receive-side circuitry while preserving the timing characteristics of mission mode Rx data path 20b. By selectively enabling test buffer 37 while disabling mission buffer 36 in the test mode, semiconductor assembly 11 can verify proper operation of the receive circuitry through data loopback 38a and clock loopback 38b without interfering with the critical timing path used during mission mode operation.

FIG. 6 is a block diagram that schematically illustrates a built-in self-test (BIST) loopback configuration implemented in a single die of semiconductor assembly 11 for wafer sort testing, in accordance with an embodiment that is described herein. In some embodiments, the diagram shows multiple Tx modules 16 arranged within bottom die 14, along with test-data injection circuit 62 and a test monitor 64. The configuration comprises a clock loopback 41 and a data loopback 42 showing multiple BIST loopback paths 66 for wafer sort testing. In the context of the present disclosure and in the claims, the terms "BIST loopback path 66" and "BIST test path 66" and grammatical variations thereof are used interchangeably. Clock loopback 41 routes the clock signal from the output pads back to the input circuitry, while data loopback 42 routes test data signals from the output pads back to the input circuitry for verification by the BIST monitoring circuitry.

In some embodiments, BIST test path 66 is shown connecting to the loopback circuitry of semiconductor assembly 11. BIST test path 66 merges with the mission-mode datapath at the injection point prior to transmission over the bidirectional GPIO pads. The configuration enables test data generated by the BIST engines to be routed through the same high-speed hardware 19 and DDR encoder 32 used during mission mode operation, and then returned through clock loopback 41 and data loopback 42 for verification. In some embodiments, multiple Tx modules 16 and Rx modules 17 are arranged in replicated slices within semiconductor assembly 11, with each slice containing clock alignment circuitry, DDR encoder circuitry, and pipelining flip-flops. Mission buffer 36 and test buffer 37 are arranged in alternating positions at each module to handle both mission mode and test mode signal paths.

In some embodiments, control logic 60 is configured to connect to the BIST TX module described above that provides test data injection. A test-data injection circuit 62 is configured for providing cascaded multiplexer structures that enable test pattern injection into the mission-mode datapath. Test-data injection circuit 62 is configured to select BIST test path 66 that merges with the mission-mode datapath at the injection point prior to transmission over the bidirectional GPIO pads. In some embodiments, test-data injection circuit 62 comprises selection circuitry that determines whether mission-mode data or test data is transmitted through the hybrid bond pad interconnects, enabling the BIST mechanism to utilize the same datapath components employed during normal operation.

In some embodiments, test monitor 64 is connected to the BIST checker circuitry that monitors the received test data through the loopback paths to detect interconnect defect 9 (shown in FIG. 2 above). Test monitor 64 analyzes the data received through data loopback 42 and compares the received data against expected values to identify single-bit failures in the hybrid bond pad 22 interconnects. The loopback connections are configured to route signals from the output pads back to the input circuitry, enabling verification of the transmit and receive hardware using the same mission-mode datapath components. In some embodiments, test monitor 64 operates in conjunction with BIST engine 24a, BIST engine 24b, BIST engine 24c, and BIST engine 24d (all shown in FIG. 3 above) to provide comprehensive testing of the hybrid bond pad 22 interconnects.

In some embodiments, semiconductor assembly 11 is configured to execute a built-in self-test (BIST) algorithm configured to detect single-bit failures in the plurality of hybrid bond pad interconnects using the at least one on-die loopback path formed by clock loopback 41 and data loopback 42. In some embodiments, the execution of the BIST algorithm comprises applying at least one stress pattern selected from: an all-ones pattern, an all-zeros pattern, a checkerboard pattern, and an inverse-checkerboard pattern that are known in the art and are not shown. In some embodiments, the BIST algorithm applies power hammer patterns comprising all ones and all zeros for stressing the power rails of interface 15. The power hammer patterns exercise the interface under conditions that reveal defects or weaknesses in the hybrid bond pad 22 interconnects by driving maximum current through the power distribution network.

In some embodiments, the BIST algorithm is configured to operate with partially populated interconnects by analyzing only a subset of payload bits that are physically connected. The BIST algorithm is executed using one or more of the on-die loopback path formed by clock loopback 41 and data loopback 42. In some embodiments, interface 15 comprises a 16-bit data path that is funneled down to 8 bits due to double data rate operation performed by DDR encoder 32, as further described with respect to a bundle of wires 50 in FIG. 8 below. In some embodiments, the BIST algorithm is configured to analyze the 16-bit interface even when only a subset of the bits are balled out and connected, with the remaining positions unused. In some embodiments, test-data injection circuit 62 and test monitor 64 are configured to handle the partially populated configuration by masking the unconnected bit positions during test pattern generation and response analysis, enabling wafer sort testing of dies with varying interconnect populations.

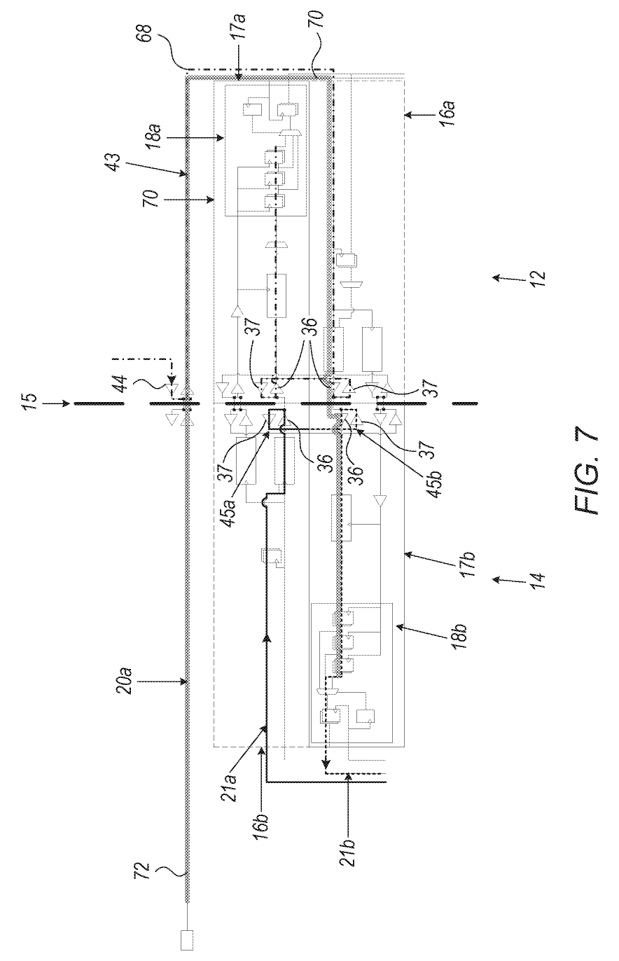

FIG. 7 is a block diagram that schematically illustrates a test clock injection configuration for wafer sort testing in top die 12 and bottom die 14 of semiconductor assembly 11, in accordance with an embodiment that is described herein. In some embodiments, the diagram shows interface 15 between the dies and identifies the various signal paths and modules involved in both mission mode and test mode operations. The configuration comprises a Tx module 16a of die 12 and a Tx module 16b of die 14, along with an Rx module 17a of die 12 and an Rx module 17b of die 14. It is noted that there Tx modules and Rx modules have the same functionality of Tx module 16 and Rx modules 17 shown, for example, in FIG. 3 above, and comprise the "a" and "b" indices for the sake of presentation and conceptual clarity. A receive FIFO 18a is associated with Rx module 17a, and a receive FIFO 18b is associated with Rx module 17b. Mission buffer 36 and test buffer 37 are distributed throughout the receive circuitry to handle both mission mode and test mode signal paths, as described for example in FIGS. 4-6 above.

In some embodiments, the diagram identifies a timing-critical stacked clock loop 72 showing the clock path that operates between top die 12 and bottom die 14 during normal stacked operation. Timing-critical stacked clock loop 72 comprises the clock transmission path from bottom die 14 to top die 12 and back to bottom die 14. In a stacked configuration, top die 12 receives its clock from bottom die 14, and the latency of data transmission is limited to the loop caused by transmission of the clock from bottom die 14 to top die 12 and back to bottom die 14. Timing-critical stacked clock loop 72 is highly timing-critical and forces the design to avoid using any logic on this path, as additional circuitry would cause a performance impact that is not acceptable for high-speed operation of the mission-mode datapath.

In some embodiments, semiconductor assembly 11 comprises a test clock injection path 68. Test clock injection path 68 is coupled to a primary clock input pad 44 that receives a test clock signal 43. Test clock signal 43 is provided on a non-timing-critical path relative to timing-critical stacked clock loop 72. During wafer sort testing, when bottom die 14 may not exist, test clock injection path 68 uses the bidirectional pads to inject a clean clock into the test circuit. In some embodiments, test clock injection path 68 is configured to provide test clock signal 43 on a non-timing-critical path during wafer sort testing, enabling the BIST mechanism to operate without requiring the presence of bottom die 14 to provide the normal clock signal through timing-critical stacked clock loop 72.

In some embodiments, semiconductor assembly 11 comprises a downstream test logic 70 shown on the right side of FIG. 7. Downstream test logic 70 receives the injected test clock through the non-timing-critical path provided by test clock injection path 68. The disclosed techniques comprise injecting test clock signal 43 via primary clock input pad 44 to clock downstream test logic 70, wherein the injected test clock is provided on a non-timing-critical clock path relative to timing-critical stacked clock loop 72 between top die 12 and bottom die 14. In some embodiments, downstream test logic 70 comprises the BIST checker circuitry and test monitoring circuitry that analyze the received test data through the loopback paths.

In some embodiments, the diagram identifies mission mode Tx data path 20a representing the most timing-critical data path. Test mode Tx data path 21a and test mode Rx data path 21b are also indicated, showing the alternative signal routing during test operations. A test mode Tx data loopback 45a and a test mode Rx data loopback 45b are shown in the central portion of FIG. 7, enabling the BIST mechanism to verify functionality during wafer sort testing. Test mode Tx data loopback 45a routes transmitted test data back to the receive circuitry on the transmit side, while test mode Rx data loopback 45b routes received test data back to the monitoring circuitry on the receive side.

In some embodiments, the configuration shown in FIG. 7 enables wafer sort testing of individual dies prior to assembly by providing test clock signal 43 through primary clock input pad 44 rather than through timing-critical stacked clock loop 72. The timing closure achieved for Tx module 16a, Tx module 16b, Rx module 17a, and Rx module 17b during mission mode design is leveraged to drive the test loopback paths. In some embodiments, semiconductor assembly 11 is shmooed by varying at least one operating parameter during the test mode to validate operation of the mission-mode datapath. The shmooing process varies voltage and timing parameters during test mode to characterize the operating margins of the mission-mode datapath and verify that the interface operates correctly across a range of conditions.

FIG. 8 is a block diagram that schematically illustrates a lane redundancy architecture for semiconductor assembly 11, in accordance with an embodiment that is described herein.

In some embodiments, the diagram depicts the data flow and redundancy mechanisms at interface 15 between bottom die 14 and top die 12 of semiconductor assembly 11. The transmit path is associated with Tx module 16 and the receive path is associated with Rx module 17, connected through bundle of wires 50.

In some embodiments, on the transmit side associated with Tx module 16, the architecture comprises several components arranged in a signal flow configuration. An input-output BIST (IOBIST) 75 is configured to provide test data for injection into the data path. IOBIST 75 corresponds to the BIST engines described in FIG. 3 above. A data input feeds into a Cyclic Redundancy Check (CRC) block 71, which adds error detection capability to the data stream. A Control/Status Registers / Fuse settings (CSRs/FUSE) block 74 provides configuration and control signals, comprising non-volatile fuse or eFuse storage and programmable CSR configuration storage used to hold repair configuration, test results, enable bits, lane and wire disable flags, and other link settings. A test-data injection circuit 73 is a multiplexer configured to select between mission-mode data from CRC block 71 and test data from IOBIST 75. Test-data injection circuit 73 corresponds to test-data injection circuit 62 and test injection circuitry and points 27, 28 described in FIGS. 3 and 6 above. A repair logic 76, also referred to as bit redundancy logic, is positioned between test-data injection circuit 73 and bundle of wires 50. In some embodiments, repair logic 76 is configured to implement bit redundancy functionality by mapping data to functional lanes. When one of the lanes is not functional, repair logic 76 is configured to shift the data to lanes that are functional.

In some embodiments, a bundle of wires 50 comprises 16-bit interfaces on both input and output sides, and a wire group 80 encompasses the bundle structure. In the present example, wire group 80 comprises a 16-bit/8-wire grouping that is applied on a given configuration of interface 15. A plurality of lanes 82 represents the individual interconnect conductors used to convey data signals between bottom die 14 and top die 12. Each of lanes 82 comprises one or more interconnect conductors of the plurality of hybrid bond pad interconnects, such as hybrid bond pad 22 shown in FIG. 2 above, used to convey a respective data signal between bottom die 14 and top die 12.

In some embodiments, on the receive side associated with Rx module 17, the architecture comprises a deskew block 79 configured to perform timing alignment of the received signals by compensating for inter-wire/inter-lane delay differences so the bits arrive and are sampled together correctly at the receiver circuitry of Rx module 17. In some embodiments, Rx module 17 comprises a repair module 86 (also referred to herein as a bit redundancy circuitry) configured to implement the repair of the data received from deskew block 79. Repair module 86 is configured to perform reverse mapping corresponding to the mapping performed by repair logic 76 on the transmit side, thereby reconstructing the original data word. In some embodiments, an IOBIST check block 85 is configured to monitor the test data. IOBIST check block 85 corresponds to test monitor 64 and Test monitoring 29, 30 described in FIGS. 3 and 6 above. Rx module 17 further comprises a CRC block 81 configured to output the data out, and a CSRs/FUSE block 84 configured to store the repair configuration and the output of the test data.

In some embodiments, the architecture supports two data paths. In test mode, data flows from IOBIST 75 through test-data injection circuit 73, repair logic 76, bundle of wires 50, deskew block 79, repair module 86, to IOBIST check block 85. In mission mode, data flows from data input through CRC block 71, the MUX serving as test-data injection circuit 73, repair logic 76, bundle of wires 50, deskew block 79, repair module 86, CRC block 81, to data output. The redundancy mapping performed by repair logic 76 and repair module 86 participates in both paths. The repair mapping, which is performed by repair logic 76 and repair module 86 maps one or more of lanes 82 to a functioning transmitter and a functioning receiver.

In some embodiments, the redundancy scheme comprises per-wire repair within wire group 80. The architecture enables detection and repair of interconnect defects without requiring distinction of whether a defect is on the transmit side or receive side of the mission-mode datapath.

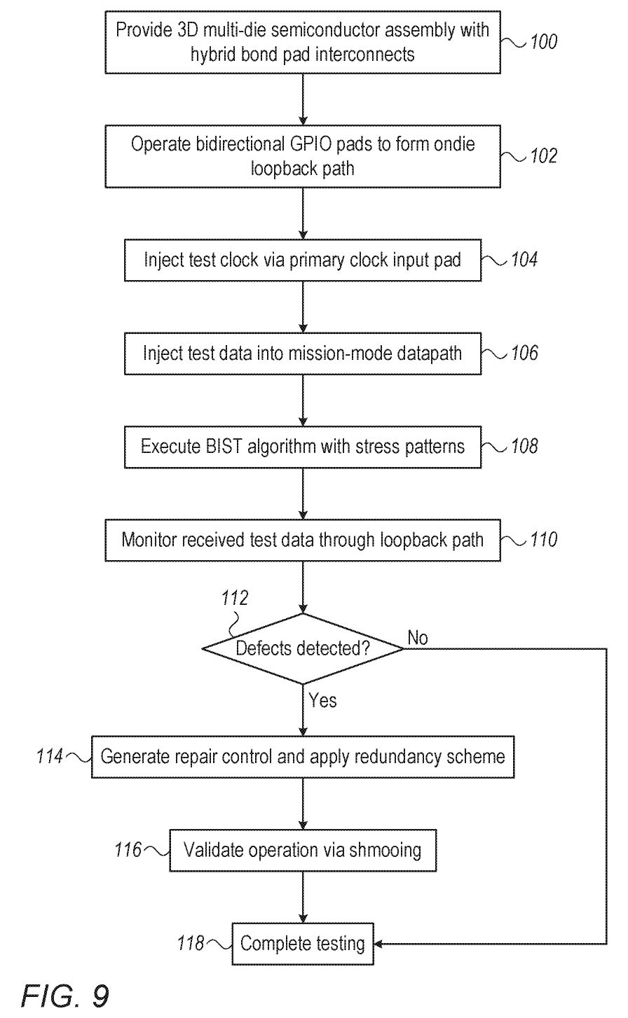

FIG. 9 is a flowchart illustrating a method for testing a three-dimensional multi-die semiconductor assembly, such as semiconductor assembly 11, in accordance with an embodiment that is described herein. The method comprises a sequence of stages that enable comprehensive testing of hybrid bond pad 22 interconnects while preserving the timing characteristics of the mission-mode datapath.

In some embodiments, the method begins with a providing step 100 in which semiconductor assembly 11 with hybrid bond pad 22 interconnects is provided. Semiconductor assembly 11 comprises top die 12 and bottom die 14 coupled by a plurality of hybrid bond pad 22 interconnects, as described with respect to FIGS. 1-3 above. At providing step 100, semiconductor assembly 11 is prepared for testing, with the plurality of bidirectional GPIO pads available for configuration in either mission mode or test mode operation.

At an operating step 102 the bidirectional GPIO pads are operated to form at least one on-die loopback path. Additionally, at operating step 102, control logic 60 switches at least a subset of the plurality of bidirectional GPIO pads to a second signal direction different from the first signal direction used during mission mode, as described with respect to FIGS. 5 and 6 above. In some embodiments, operating step 102 comprises reusing an output driver, which is idle during the mission mode, to drive a return signal into an input pad to implement the on-die loopback path. The on-die loopback path is formed on at least one of top die 12 and bottom die 14, enabling wafer sort testing on the respective die prior to coupling the other die.

At a clock injection step 104, test clock signal 43 is injected via primary clock input pad 44. At clock injection step 104, test clock signal 43 is provided on a non-timing-critical clock path relative to timing-critical stacked clock loop 72 between top die 12 and bottom die 14, as described with respect to FIG. 7 above. In some embodiments, test clock injection path 68 provides test clock signal 43 to downstream test logic 70 during wafer sort testing when bottom die 14 is not present to provide the normal clock signal through timing-critical stacked clock loop 72.

At a data injection step 106, test data is injected into the mission-mode datapath at an injection point that is not on a critical timing path for mission-mode operation. In some embodiments, test-data injection circuit 62 selects BIST test path 66 that merges with the mission-mode datapath at the injection point prior to transmission over the bidirectional GPIO pads, as described with respect to FIG. 6 above. The circuitry used for test injection is not in series with the critical timing path for mission-mode operation during the mission mode, preserving the timing characteristics that physical design optimization has achieved for the mission-mode interface.

At a BIST execution step 108, a built-in self-test algorithm is executed with stress patterns. In some embodiments, BIST engine 24a, BIST engine 24b, BIST engine 24c, and BIST engine 24d generate test patterns that are transmitted through the on-die loopback path formed by data loopback 33a, clock loopback 33b, data loopback 38a, clock loopback 38b, data loopback 42, and clock loopback 41, as described with respect to FIGS. 4 - 6 above. In some embodiments, BIST execution step 108 comprises applying at least one stress pattern selected from: an all-ones pattern, an all-zeros pattern, a checkerboard pattern, and an inverse-checkerboard pattern. The BIST algorithm applies power hammer patterns comprising all ones and all zeros for stressing the power rails of interface 15.

At a monitoring step 110, received test data is monitored through the on-die loopback path to verify that the transmitted test patterns are correctly received. In some embodiments, test monitor 64 and Test monitoring 29 and 30 analyze the data received through the loopback paths and compare the received data against expected values to identify failures in hybrid bond pad 22 interconnects, as described with respect to FIGS. 3 above (as well as in FIG. 6 above). In some embodiments, the monitoring is performed using receive circuitry of the mission-mode datapath, and control logic 60 selectively enables test buffer 37, which is idle during the mission mode, while disabling mission buffer 36 in the test mode.

At a defect detection step 112 (which is a decision step) determines whether interconnect defect 9 is detected in the hybrid bond pad 22 interconnects. In some embodiments, test monitor 64 evaluates the results of monitoring step 110 to determine whether any failures have been identified. In some embodiments, a detected failure in the on-die loopback path is not required to distinguish whether interconnect defect 9 is on a transmit side or a receive side of the mission-mode datapath. If interconnect defect 9 is detected ("Yes" path from defect detection step 112), the method proceeds to a repair generation step 114. If no defects are detected ("No" path from defect detection step 112), the method proceeds directly to a completion step 118, bypassing repair generation step 114 and a validation step 116.

At a repair generation step 114, repair control is generated and a redundancy scheme is applied in response to defects detected by monitoring step 110. In some embodiments, the redundancy scheme comprises per-wire repair within wire group 80, as implemented by lane repair MUXs 23 and repair logic 76 described with respect to FIGS. 3 and 8 above. At repair generation step 114, repair mapping is configured to map one or more of lanes 82 to a functioning transmitter and a functioning receiver. In response to a single failure indication produced by monitoring step 110, semiconductor assembly 11 selects a repair that applies to a transmitter-side lane and a receiver-side lane associated with a same interconnect, without distinguishing whether interconnect defect 9 is on a transmit side or a receive side of the mission-mode datapath.

At validation step 116 the operation is validated via shmooing. In some embodiments, semiconductor assembly 11 is shmooed by varying at least one operating parameter during the test mode to validate operation of the mission-mode datapath, e.g., at a data rate that is at least a threshold percentage of a mission-mode data rate. In some embodiments, the shmooing process varies voltage and timing parameters during test mode to characterize the operating margins of the mission-mode datapath and verify that interface 15 operates correctly across a range of conditions. The timing closure achieved for Tx module 16 and Rx module 17 during mission mode design is leveraged to drive the test loopback paths at near mission-mode speeds during validation step 116.

In some embodiments, the method concludes with completion step 118 in which testing is completed. At completion step 118, semiconductor assembly 11 has been verified for proper functionality of hybrid bond pad 22 interconnects, and any detected defects have been addressed through the redundancy scheme applied at repair generation step 114. Semiconductor assembly 11 is then ready for further processing, which comprises assembly of top die 12 and bottom die 14 if wafer sort testing was performed on individual dies, or deployment in a system if module-level testing was performed on the assembled semiconductor assembly 11.

The configurations of semiconductor assembly 11 and its components, e.g., dies 12 and 14, their Tx module 16, Rx module 17, BIST engines 24a, 24b and 24c, the data paths, the test paths, the clock paths, the loopbacks of data, test and clock, and the components of interface 15 (such as but not limited to hybrid bond pads 22, the GPIO light pads, the bus architecture, and the wires and bundle of wires 50 and lanes 82) between dies 12 and 14, as illustrated in FIGS. 2-8, are example configurations chosen purely for the sake of conceptual clarity. In alternative embodiments, any other suitable configuration can be used. The logic circuits and controllers and their components, e.g., control logic components 60 and 70, repair logic 76 and repair module 86, test monitor 64, test-data injection circuit 62, and CSRs/FUSE blocks 74 and 84, may be implemented using suitable hardware, such as in one or more Application-Specific Integrated Circuits (ASICs) or Field- Programmable Gate Arrays (FPGAs), or central processing units (CPU) or controllers, using software, or using a combination of hardware and software elements. Elements that are not mandatory for understanding of the disclosed techniques have been omitted from the figure for the sake of clarity.

In some embodiments, certain functions of the logic circuits and controllers may be implemented in a general-purpose processor, which is programmed in software to carry out the functions described herein. The software may be downloaded to the processor in electronic form, over a network, for example, or it may, alternatively or additionally, be provided and/or stored on non-transitory tangible media, such as magnetic, optical, or electronic memory.

Although the embodiments described herein mainly address methods and systems for testing 3D semiconductor assemblies, the methods and systems described herein can also be used in other applications.

It is noted that the embodiments described above are cited by way of example, and that the present invention is not limited to what has been particularly shown and described hereinabove. Rather, the scope of the present invention includes both combinations and sub-combinations of the various features described hereinabove, as well as variations and modifications thereof which would occur to persons skilled in the art upon reading the foregoing description and which are not disclosed in the prior art. Documents incorporated by reference in the present patent application are to be considered an integral part of the application except that to the extent any terms are defined in these incorporated documents in a manner that conflicts with the definitions made explicitly or implicitly in the present specification, only the definitions in the present specification should be considered.

1. A method for testing a semiconductor assembly, the method comprising:
in a three-dimensional (3D) multi-die semiconductor assembly comprising a first die and a second die coupled by a plurality of hybrid bond pad interconnects, operating a mission-mode datapath between the first die and the second die using bidirectional general purpose input output (GPIO) pads that are configured for a first signal direction during a mission mode;
operating, in a test mode, at least a subset of the bidirectional GPIO pads at a second signal direction different from the first signal direction to form at least one on-die loopback path;
injecting test data into the mission-mode datapath at an injection point that is not on a critical timing path for a mission-mode operation of the mission-mode datapath; and
monitoring received test data through the at least one on-die loopback path to detect at least one interconnect defect associated with the plurality of hybrid bond pad interconnects.

2. The method according to claim 1, wherein circuitry used for test injection and test monitoring is not in series with the critical timing path for the mission-mode operation during the mission mode and wherein the at least one on-die loopback path is formed on one of the first die and second die.

3. The method according to claim 1, wherein operating the at least a subset of the bidirectional GPIO pads comprises reusing an output driver, which is idle during the mission mode, to drive a return signal into an input pad to implement the at least one on-die loopback path.

4. The method according to claim 1, wherein the monitoring is performed using receive circuitry of the mission-mode datapath, and wherein the method further comprises selectively enabling a test buffer, which is idle during the mission mode, while a mission buffer remains idle in the test mode.

5. The method according to claim 1, further comprising injecting a test clock via a primary clock input pad to clock downstream test logic, wherein the injected test clock is provided on a non-timing-critical clock path relative to a timing-critical stacked clock loop between the first die and the second die.

6. The method according to claim 1, further comprising executing a built-in self-test (BIST) algorithm configured to detect single-bit failures in the plurality of hybrid bond pad interconnects using the at least one on-die loopback path, wherein executing the BIST algorithm comprises applying at least one stress pattern selected from: an all-ones pattern, an all-zeros pattern, a checkerboard pattern, and an inverse-checkerboard pattern.

7. The method according to claim 1, further comprising executing a built-in self-test (BIST) algorithm configured to operate with partially populated interconnects by analyzing only a subset of payload bits that are physically connected, wherein the BIST algorithm is executed using the at least one on-die loopback path.

8. The method according to claim 1, further comprising generating a repair control for a redundancy scheme in response to defects detected by the monitoring, the redundancy scheme comprising per-wire repair within a group of wires.

9. The method according to claim 8, wherein the redundancy scheme further comprises: performing, by a deskew block on a receive side of the mission-mode datapath, timing alignment of received signals by compensating for inter-wire delay differences; and performing, by a repair module on the receive side, reverse mapping corresponding to mapping performed by repair logic on a transmit side of the mission-mode datapath, thereby reconstructing an original data word.

10. The method according to claim 8, wherein generating the repair control comprises storing repair configuration in at least one of a non-volatile fuse storage and a programmable configuration storage, the repair configuration comprising at least one of: test results, enable bits, lane disable flags, and wire disable flags.

11. The method according to claim 1, wherein in the monitoring, a detected failure in the at least one on-die loopback path is not required to distinguish whether a defect is on a transmit side or a receive side of the mission-mode datapath, and wherein a repair is performed at the 3D multi-die semiconductor assembly by configuring repair mapping to map one or more lanes to a functioning transmitter and a functioning receiver, wherein each of the one or more lanes comprises one or more interconnect conductors of the plurality of hybrid bond pad interconnects used to convey a respective data signal between the first die and the second die.

12. The method according to claim 1, wherein injecting test data comprises selecting a built-in self-test (BIST) test path that merges with the mission-mode datapath at the injection point prior to transmission over the bidirectional GPIO pads.

13. The method according to claim 1, further comprising shmooing the 3D multi-die semiconductor assembly by varying at least one operating parameter during the test mode to validate operation of the mission-mode datapath.

14. The method according to claim 1, further comprising, in response to a single failure indication produced by the monitoring, selecting a repair that applies to a transmitter-side lane and a receiver-side lane associated with a same interconnect, without distinguishing whether a defect is on a transmit side or a receive side of the mission-mode datapath.

15. A system for testing a semiconductor assembly, the system comprising:
a first die comprising a transmit circuit and a receive circuit coupled to a plurality of bidirectional general purpose input output (GPIO) pads;
a second die configured to be coupled to the first die by a plurality of hybrid bond pad interconnects that are connected to the plurality of bidirectional GPIO pads;
control logic configured to, (i) in a mission mode, set the plurality of bidirectional GPIO pads to a first signal direction for a mission-mode data transfer, and, (ii) in a test mode, switch at least a subset of the plurality of bidirectional GPIO pads to a second signal direction different from the first signal direction to create at least one on-die loopback path;
a test-data injection circuit configured to inject test data into a mission-mode datapath at an injection point that is not on a critical timing path for a mission-mode operation of the mission-mode datapath; and
a test monitor configured to monitor received test data through the at least one on-die loopback path to detect at least one interconnect defect associated with the plurality of hybrid bond pad interconnects.

16. The system according to claim 15, wherein the circuitry used for test injection and test monitoring is not in series with the critical timing path for the mission-mode operation during the mission mode and wherein the control logic is configured to enable wafer sort testing on the first die by using the at least one on-die loopback path prior to coupling the second die to the first die.

17. The system according to claim 15, further comprising a test clock injection path coupled to a primary clock input pad, the test clock injection path configured to provide a test clock on a non-timing-critical path during wafer sort testing.

18. The system according to claim 15, further comprising repair logic configured to perform per-wire repair within a wire group.

19. The system according to claim 15, wherein the receive circuit comprises a mission buffer and a test buffer, and the control logic is configured to use the mission buffer in the mission mode and use the test buffer in the test mode.

20. The system according to claim 15, wherein the test-data injection circuit is configured to select a built-in self-test (BIST) test path that merges with the mission-mode datapath at the injection point prior to transmission over the bidirectional GPIO pads.
